(19) United States
(12) Patent Application Publication
(10) Pub. No.: US 2009/0098670 A1
(43) Pub. Date: Apr. 16, 2009

(54) SEMICONDUCTOR DEVICE FOR MONITORING CURRENT CHARACTERISTIC AND MONITORING METHOD FOR CURRENT CHARACTERISTIC OF SEMICONDUCTOR DEVICE

(76) Inventor: Ji-Ho Hong, Hwaseong-si (KR)

Correspondence Address: SHERR & VAUGHN, PLLC, 620 HERNDON PARKWAY, SUITE 200, HERNDON, VA, 20170, US

(21) Appl. No.: 12/249,088

(22) Filed: Oct. 10, 2008

(30) Foreign Application Priority Data
Oct. 15, 2007 (KR) 10-2007-0103370

(51) Int. Cl. H01L 21/66

(52) U.S. Cl. 438/17; 257/E21.531

(57) ABSTRACT

A method for monitoring current characteristics of a semiconductor device includes forming an isolation layer and a well area over a substrate, and then forming a P+ area and an N+ area spaced apart by the isolation layer to define active areas, and then forming a gate oxide layer over the substrate including the P+ area and the N+ area, and then forming a polysilicon layer over one of the N+ area and the P+ area, and then connecting a electronic measuring probe to one of the N+ area and the P+ area and connecting a power terminal to the polysilicon layer, and then measuring the current characteristics of the semiconductor device using the polysilicon layer as a power pad and one of the N+ area and the P+ area as a pad.

The present application claims priority under 35 U.S.C. § 119 to Korean Patent Application No. 10-2007-0103370 (filed on Oct. 15, 2007), the contents of which are incorporated in its entirety.

### BACKGROUND

As semiconductor devices have become highly integrated, there is difficulty in operation of the semiconductor devices. In the case of a MOS transistor, the size of a gate/source/drain electrode is reduced, so that the channel length is also reduced. If the channel length is reduced, short channel effect (SCE) or reverse short channel effect (RSCE) may occur, so that threshold voltage of a transistor may not be easily adjusted. In addition, since higher driving voltage is applied to the highly integrated semiconductor device having a small size, electrons supplied from a source may be excessively accelerated due to the potential gradient of a drain, so that the hot carrier may occur in the vicinity of the drain. Such a stress phenomenon due to reduction in the size of the active area must be primarily considered when designing the semiconductor devices or determining process conditions. Leakage current can be controlled by adjusting a width of an active area, which may be determined when the semiconductor device is designed, and conditions of unit processes. In particular, in the case of a low power product group that requires minimum leakage current in the voltage standby state and operation state, the above factor is very important. Thus, when designing the semiconductor device or a test element group (TEG), it is necessary to precisely determine the width of the active area and the conditions of unit processes that optimize the leakage current.

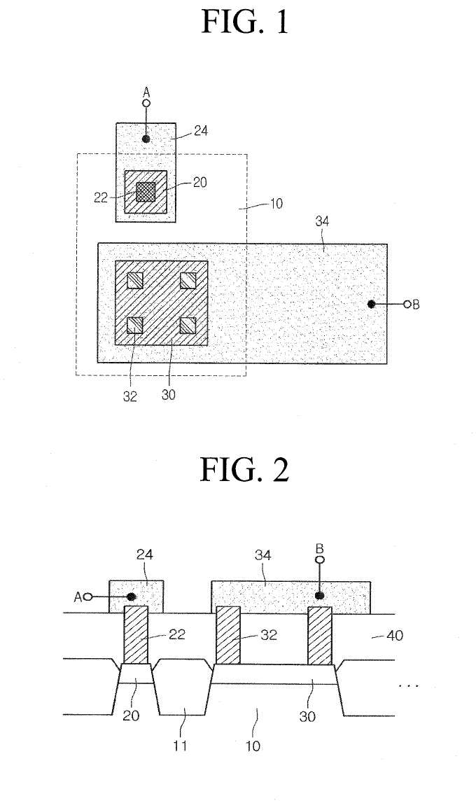

Example FIGS. 1 and 2 illustrate a top and side sectional views of a configuration for measuring leakage current of a semiconductor device. As illustrated in example FIGS. 1 and 2, the semiconductor device includes P+ area 20 and N+ area 30 which are spaced part from each other by isolation layer 11 on and/or over P-well 10. In addition, the semiconductor device includes metal lines 22, 32 which electrically connect P+ area 20 and N+ area 30 to P-type electrode 24 and N-type electrode 34, respectively, and insulating layer 40 on and/or over which metal lines 22, 32 are formed. After forming insulating layer 40, metal lines 22, 32, P-type electrode 24 and N-type electrode 34 on and/or over a substrate having P+ area 20 and N+ area 30, leakage current between the active area and P-well 10 can be electrically measured using a TEC. Meaning, after forming P-type electrode 24 and N-type electrode 34, probe A is electrically connected to P-type electrode 24 to measure current leaked to P-well 10, and power source B is electrically connected to N-type electrode 34 to measure the leakage current.

The optimum width of the active area and conditions of the unit processes can be determined by checking the current leakage. However, metal layers such as metal lines 22, 32 P-type electrode 24 and N-type electrode 34, are formed through several steps and long measurement time is required. Such a measurement scheme does not take specific effects into consideration. Thus, a new measurement scheme capable of rapidly and precisely monitoring stress of the active area is required.

### SUMMARY

Embodiments relate to a semiconductor device for monitoring current characteristic and a method for monitoring the current characteristic of the semiconductor device, which can rapidly and precisely measure an affect of stress occurring in an active area of a highly integrated semiconductor device before a process has been completed without requiring an additional measurement process.

Embodiments relate to a device for monitoring the current characteristic of semiconductor device that may include at least one of the following: a well area formed on and/or over a substrate; a P+ area and an N+ area formed on and/or over an upper portion of the well area of the substrate; an isolation layer for isolating the P+ area from the N+ area; and a polysilicon layer formed on and/or over at least one of the P+ area and the N+ area.

Embodiments relate to a method for monitoring current characteristic of a semiconductor device that may include at least one of the following: forming a shallow trench isolation layer defining an active region in a semiconductor substrate; and then forming a P-well area in the semiconductor substrate after forming the shallow trench isolation layer; and then forming a P+ area and an N+ area over the active area of the semiconductor substrate using the shallow trench isolation layer as an ion implantation mask; and then forming a gate oxide layer over the semiconductor substrate including the P+ area and the N+ area; and then removing a portion of the gate oxide layer formed over the N+ area; and then forming a polysilicon layer over the N+ area after removing the gate oxide layer; and then forming a silicide layer over the polysilicon layer by performing a silicidation process; and then measuring the current characteristics of the semiconductor device using the polysilicon layer as a power pad and the P+ area as a pad.

Embodiments relate to a method for monitoring current characteristic of a semiconductor device that may include at least one of the following: forming an isolation layer and a well area over a substrate; and then forming a P+ area and an N+ area spaced apart by the isolation layer to define active areas; and then forming a gate oxide layer over the substrate including the P+ area and the N+ area; and then forming a polysilicon layer over one of the N+ area and the P+ area; and then connecting a electronic measuring probe to one of the N+ area and the P+ area and connecting a power terminal to the polysilicon layer; and then measuring the current characteristics of the semiconductor device using the polysilicon layer as a power pad and one of the N+ area and the P+ area as a pad.

Embodiments relate to a method that may include at least one of the following: forming an isolation layer and a well area on and/or over a substrate; forming a shallow trench isolation layer defining an active region in a semiconductor substrate; and then forming a P-well area in the semiconductor substrate after forming the shallow trench isolation layer; and then forming a P+ area and an N+ area over the active area of the semiconductor substrate using the isolation layer as an ion implantation mask; and then forming a gate oxide layer over the semiconductor substrate including the P+ area and the N+ area; and then removing at least a portion of the gate oxide layer formed over the P+ area and the N+ area; and then forming a polysilicon layer over the N+ area after removing the gate oxide layer; and then forming a silicide layer over the polysilicon layer by performing a silicidation process; and then measuring current characteristics using the polysilicon layer as a power pad and the P+ area as a pad.

Embodiments relate to a method for monitoring current characteristic of a semiconductor device that may include at least one of the following: forming an isolation layer defining an active region in a semiconductor substrate; and then forming a well area in the semiconductor substrate after forming the isolation layer; and then forming a P+ area and an N+ area over the active area of the semiconductor substrate using the isolation layer as an ion implantation mask; and then forming a gate oxide layer over the semiconductor substrate including the P+ area and the N+ area; and then removing at least a portion of the gate oxide layer formed over the P+ area; and then forming a polysilicon layer over the P+ area after removing the gate oxide layer; and then measuring current characteristics using the polysilicon layer as a power pad and the N+ area as a pad.

### DRAWINGS

Example FIGS. 1 and 2 illustrate a configuration for measuring leakage current of a semiconductor device.

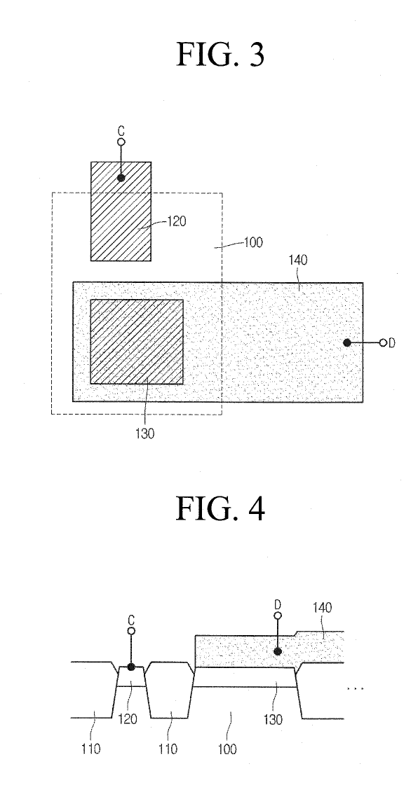

Example FIGS. 3 and 4 illustrate a configuration for measuring leakage current of a semiconductor device in accordance with embodiments.

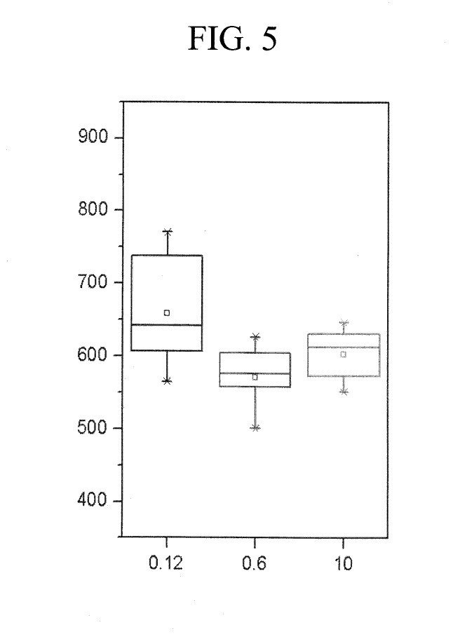

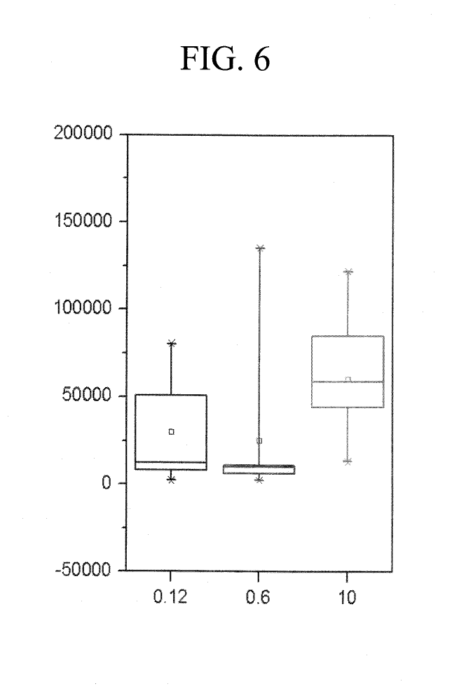

Example FIGS. 5 and 6 are graphs illustrating a relationship between an active area versus driving current and an active area versus leakage current measured using a semiconductor device for measuring leakage current in accordance with embodiments.

### DESCRIPTION

Hereinafter, a semiconductor device for monitoring current characteristic and a method for monitoring the current characteristic of the semiconductor device will be described in detail with reference to accompanying example drawings figures. For the purpose of convenience of explanation, the semiconductor device and the monitoring method thereof will be explained simultaneously.

Example FIGS. 3 and 4 are a top and side sectional views illustrating a configuration for measuring leakage current of a semiconductor device in accordance with embodiments. As illustrated in example FIGS. 3 and 4, the semiconductor device for monitoring current characteristic according includes a substrate formed with P-well 100, P+ area 120 and N+ area 130 formed on and/or over P-well 100 to serve as an active area, isolation layer 110 for electrically isolating P+ area 120 from N+ area 130, and polysilicon layer 140 formed on and/or over N+ area 130.

A method of forming the semiconductor device for monitoring current characteristic and the monitoring method thereof will be explained. Isolation layer 110 is formed in the semiconductor substrate, such as a single crystalline silicon substrate, to electrically isolate the active areas, i.e., P+ area 120 and N+ area 130, from each other. Isolation layer 110 can be formed on and/or over a field area of the semiconductor substrate in the form of an insulating layer such as an oxide layer, through an isolation process such as a shallow trench isolation (STI) process. Then, a P+ ion implantation process is performed to form P-well 100. The ion implantation can be performed after isolation layer 110 has been formed in order to adjust threshold voltage VT, to prevent punch through, and to form a channel stopper. Then, P+ area 120 and N+ area 130 are formed on and/or over the active area of the substrate using isolation layer 110 as an ion implantation mask. For instance, in order to form P+ area 120, P-type impurities such as boron (B) ions, are implanted in the substrate formed with P-well 100 using an ion implantation energy in a range between approximately 3 to 20 KeV and an ion implantation concentration in a range between approximately 1×10¹⁵˜5×10^{15 ions/cm}². For reference, arsenic (As) ions can be implanted to form the N-well, and an ion implantation masking layer, such as a photoresist layer pattern, can be used to form the well area. If P+ area 120 and N+ area 130 have been formed, an etching process is performed to remove gate oxide existing between the active area including P+ area 120 and N+ area 130 and polysilicon layer 140. Meaning, a dry etching process or a wet etching process is performed after forming a photoresist pattern, in which N+ area 130 is exposed through a photolithography process. After that, the photoresist pattern used for the etching process is removed.

If a gate oxide formed on and/or over N+ area 130 has been removed, polysilicon is coated on and/or over the substrate including isolation layer 110 and the active area. Then, a photoresist pattern is formed through a photolithography process such that polysilicon on and/or over N+ area 130 is exposed by performing an etching process. The etching process may include a dry etching process or a wet etching process. If polysilicon layer 140 is formed on and/or over N+ area 130, silicidation process is performed with respect to polysilicon layer 140. For instance, the silicidation process for polysilicon layer 140 can be performed by sputtering metal having a high melting point or heat treating polysilicon layer 140. In this case, resistance of polysilicon layer 140 is significantly lowered, so that current characteristic can be measured using polysilicon layer 140 as a pad.

In accordance with embodiments, a semiconductor device for monitoring current characteristic manufactured through the above processes, probe C of a measurement equipment is electrically connected to P+ area 120 and power source (V_{cc}, D) is electrically connected to polysilicon layer 140 to measure the current characteristic. The semiconductor device for monitoring the current characteristic in accordance with embodiments does not require an insulating layer deposition process, a contact forming process, and a metal line forming process. In addition, P+ area 120 is used as a pad for measurement equipment and polysilicon layer 140 is used as a power pad so that the current characteristic can be rapidly and precisely measured. Thus, the process can be simplified and the measurement can be repeated several times within a short period of time. Accordingly, the optimum width of the active area and process conditions can be easily found.

Measurement results obtained by using the semiconductor device for monitoring current characteristic in accordance with embodiments is as follows. Example FIG. 5 is a graph illustrating the relationship between the active area and the driving current while example FIG. 6 is a graph illustrating the relationship between the active area and the leakage current. The measurement was performed with respect to a 90 nm-level nMOS at constant operational voltage while varying the width of the active area into 0.12 μm, 0.6 μm, and 10 μm. In the graph illustrated in example FIG. 5, the X-axis represents the width of the active area and the Y-axis represents driving current (μA/μm). In the graph illustrated in example FIG. 6, the X-axis represents the width of the active area and the Y-axis represents leakage current (pA/μm).

As illustrated in example FIGS. 5 and 6, when the width of the active area is 0.12 μm, the leakage current and the driving current can be increased. Meaning, if the profile of the semiconductor device becomes reduced, the active area is influenced by electric stress. In this manner, in accordance with the semiconductor device for monitoring the current characteristic, the current characteristic can be precisely measured in accordance with the width of the active area. With the push for producing highly integrated semiconductor devices, the precise measurement of the current characteristic is very important to design the semiconductor device.

Another measurement result is shown in Table 1, which 1 illustrates the leakage current between the active area and the well area according to variation of the size of the active area. Two types of active areas are illustrated in Table 1, in which the active areas signify areas coupled to the well area.

TABLE 1

| Active area | Leakage current | | Minimum active |
|---|---|---|---|
| (μm²) | N+ area: P-well | P+ area: N-well | area (μm²) |
| 0.49 | 0.14 (pA/μm²) | 0.08 (pA/μm²) | 0.06 |
| 0.042 | 0.61 (mA/μm²) | 0.57 (mA/μm²) | |

As can be understood from Table 1, if the size of the active area is smaller than 0.06 μm², which is a minimum size defined in the design rule of a 90 nm logic process, i.e., if the size of the active area is 0.042 μm², greater leakage current is generated from the N+ area and the P+ area as compared with a case in which the size of the active area is 0.49 μm². It can be understood that the semiconductor device for monitoring current characteristic and the monitoring method thereof in accordance with embodiments can finely measure the current characteristic based on the size and width of the active area.

In accordance with embodiments, the measurement system is advantageous for at least the following reasons. First, the affect of stress generated from the active area of the semiconductor device, for instance, the current characteristic, such as an amount of driving current and leakage current, can be rapidly and precisely measured, so that the profile of the semiconductor device can be efficiently designed. Thus, the development period for the semiconductor device can be shortened. Second, the affect of the stress generated from the active area can be found in the process of manufacturing the semiconductor device without performing an additional process, so that the semiconductor manufacturing process can be rapidly performed. Thus, the process can be simplified, and the manufacturing time and cost can be reduced, so that the product yield of the semiconductor devices can be maximized.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for monitoring current characteristics of a semiconductor device comprising:
forming a shallow trench isolation layer defining an active region in a semiconductor substrate; and then
forming a P-well area in the semiconductor substrate after forming the shallow trench isolation layer; and then
forming a P+ area and an N+ area over the active area of the semiconductor substrate using the shallow trench isolation layer as an ion implantation mask; and then
forming a gate oxide layer over the semiconductor substrate including the P+ area and the N+ area; and then
removing a portion of the gate oxide layer formed over the N+ area; and then
forming a polysilicon layer over the N+ area after removing the gate oxide layer; and then
forming a silicide layer over the polysilicon layer by performing a silicidation process; and then
measuring the current characteristics of the semiconductor device using the polysilicon layer as a power pad and the P+ area as a pad.

2. The method of claim 1, wherein removing the gate oxide layer comprises etching a surface of one of the N+ area through a wet etching process.

3. The method of claim 1, wherein forming the P+ area comprises implanting boron ions in the P-well area and forming the N+ area comprises implanting arsenic ions in the P-well area.

4. A method for monitoring current characteristics of a semiconductor device comprising:
forming an isolation layer and a well area over a substrate; and then
forming a P+ area and an N+ area spaced apart by the isolation layer to define active areas; and then
forming a gate oxide layer over the substrate including the P+ area and the N+ area; and then
forming a polysilicon layer over one of the N+ area and the P+ area; and then
connecting a electronic measuring probe to one of the N+ area and the P+ area and connecting a power terminal to the polysilicon layer; and then
measuring the current characteristics of the semiconductor device using the polysilicon layer as a power pad and one of the N+ area and the P+ area as a pad.

5. The method of claim 4, wherein the well area comprises a P-well.

6. The method of claim 5, wherein the polysilicon layer is formed over the N+ area.

7. The method of claim 4, further comprising, after forming the gate oxide layer and before forming the polysilicon layer, removing the gate oxide layer formed over one of the P+ area and the N+ area.

8. The method of claim 7, wherein removing the gate oxide layer comprises etching a surface of one of the N+ area and the P+ area through a wet etching process.

9. The method of claim 8, wherein the wet etching process comprises:
forming a photoresist layer pattern exposing one of the N+ area and the P+ area; and then
performing the wet etching process.

10. The method of claim 7, wherein removing the gate oxide layer comprises etching a surface of one of the N+ area and the P+ area formed through a dry etching process.

11. The method of claim 10, wherein the dry etching process comprises:
forming a photoresist layer pattern exposing one of the N+ area and the P+ area; and then
performing the dry etching process.

12. The method of claim 4, wherein the polysilicon layer is subject to a silicidation process.

13. A method comprising:
forming an isolation layer defining an active region in a semiconductor substrate; and then
forming a well area in the semiconductor substrate after forming the isolation layer; and then
forming a P+ area and an N+ area over the active area of the semiconductor substrate using the isolation layer as an ion implantation mask; and then
forming a gate oxide layer over the semiconductor substrate including the P+ area and the N+ area; and then
removing at least a portion of the gate oxide layer formed over the P+ area; and then
forming a polysilicon layer over the P+ area after removing the gate oxide layer; and then
measuring current characteristics using the polysilicon layer as a power pad and the N+ area as a pad.

14. The method of claim 13, wherein the well area comprises a P-well formed by performing a P+ ion implantation process in the semiconductor substrate.

15. The method of claim 13, wherein the semiconductor substrate comprises a single crystalline silicon substrate.

16. The method of claim 13, wherein forming the isolation layer comprises forming an insulating layer over a field area of the substrate in the form of an insulating layer using shallow trench isolation process.

17. The method of claim 13, wherein forming the P+ area comprises implanting boron ions in the well area.

18. The method of claim 17, wherein the boron ions are implanted using an ion implantation energy in a range between approximately 3 to 20 KeV and an ion implantation concentration in a range between approximately 1×10¹⁵ to 5×10¹⁵ ions/cm².

19. The method of claim 17, wherein forming the N+ area comprises implanting arsenic ions in the well area.

20. The method of claim 13, further comprising, after forming the polysilicon layer and before measuring current characteristics, forming a silicide layer over the polysilicon layer.
